(19) United States
(12) Patent Application Publication
(10) Pub. No.: US 2025/0100420 A1
(43) Pub. Date: Mar. 27, 2025

(54) VEHICLE CONTROL APPARATUS AND NON-TRANSITORY RECORDING MEDIUM

(71) Applicant: SUBARU CORPORATION, Tokyo (JP)

(72) Inventor: Ryo KIKKAWA, Tokyo (JP)

(21) Appl. No.: 18/887,189

(22) Filed: Sep. 17, 2024

(30) Foreign Application Priority Data
Sep. 26, 2023 (JP) 2023-164008

(51) Int. Cl. B60L 58/13

(52) U.S. Cl. CPC B60L 58/13; B60L 2240/14; B60L 2240/423; B60L 2260/54

(57) ABSTRACT

A vehicle control apparatus is configured to estimate a voltage value of a battery mounted on a vehicle, without using a voltage sensor configured to measure the voltage value of the battery or a current sensor configured to measure a current value of the battery. The vehicle control apparatus includes a processor and a memory. The memory is configured to store a program to be executed by the processor. The program includes a command. The command causes the processor to execute a processing including: calculating, as estimated values, a desired electric power amount and the current value that are estimated to be used to drive the vehicle; and estimating the voltage value of the battery, based on the calculated estimated values of the desired electric power amount and the current value.

### CROSS-REFERENCE TO RELATED APPLICATIONS

The present application claims priority from Japanese Patent Application No. 2023-164008 filed on Sep. 26, 2023, the entire contents of which are hereby incorporated by reference.

### BACKGROUND

The disclosure relates to a vehicle control apparatus and a non-transitory recording medium to be applied to, for example, an electrically powered vehicle such as an electric vehicle including a battery.

An electrically powered vehicle including an electric motor configured to be driven by electric power supplied from a battery includes a controller that detects a state of the battery. Such an electrically powered vehicle controls charging and discharging of the battery by controlling a driving state of the electric motor, an inverter, etc. based on the state of the battery detected by the controller described above.

The in-vehicle battery is an element that supplies electric power to be used to drive the electrically powered vehicle and is configured to, for example, drive the electric motor by passing a desired current through the inverter. Thus, the electric motor is to be supplied with an appropriate current from the battery to be driven. Japanese Unexamined Patent Application Publication (JP-A) No. 2014-205386 proposes preventing excessive charging and discharging of a battery upon a malfunction in a controller.

### SUMMARY

An aspect of the disclosure provides a vehicle control apparatus configured to estimate a voltage value of a battery mounted on a vehicle, without using a voltage sensor configured to measure the voltage value of the battery or a current sensor configured to measure a current value of the battery. The vehicle control apparatus includes a processor and a memory. The memory is configured to store a program to be executed by the processor. The program includes a command. The command causes the processor to execute a processing including: calculating, as estimated values, a desired electric power amount and the current value that are estimated to be used to drive the vehicle; and estimating the voltage value of the battery, based on the calculated estimated values of the desired electric power amount and the current value.

An aspect of the disclosure provides a non-transitory tangible computer readable recording medium containing a voltage value estimation program configured to estimate a voltage value of a battery mounted on a vehicle, without using a voltage sensor configured to measure the voltage value of the battery or a current sensor configured to measure a current value of the battery. The voltage value estimation program causes, when executed by a processor, the processor to implement a method. The method includes: calculating, as estimated values, a desired electric power amount and the current value that are estimated to be used to drive the vehicle; and estimating the voltage value of the battery, based on the calculated estimated values of the desired electric power amount and the current value.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the disclosure. FIG. 1 is a schematic diagram illustrating a configuration example of an electrically powered vehicle according to one example embodiment.

FIG. 2 is a block diagram illustrating the electrically powered vehicle according to one example embodiment.

FIG. 3 is a block diagram illustrating a vehicle control apparatus and peripheral devices thereof to be mounted on the electrically powered vehicle according to one example embodiment.

FIG. 4 is a schematic diagram illustrating a known battery model using an RC equivalent circuit.

FIG. 5 is a flowchart illustrating a voltage estimation method according to one example embodiment.

FIG. 6 is a block diagram illustrating an electrically powered vehicle according to one example embodiment.

FIG. 7 is a flowchart illustrating a voltage estimation method according to one example embodiment.

FIG. 8 is a schematic diagram illustrating a first vehicle motion model (one-wheel model).

### DETAILED DESCRIPTION

Existing techniques, including JP-A No. 2014-205386, seem not to satisfy market needs appropriately. For example, assuming an electrically powered vehicle in practical use, aging or a malfunction can cause some abnormality in a voltage sensor or a current sensor for monitoring a voltage value of a battery, which can result in a situation in which the voltage sensor or the current sensor is inoperable.

Even if an abnormality occurs in the voltage sensor or the current sensor and a device that directly measures the voltage value of the battery becomes unavailable as described above, it is desired to include a system that indirectly estimates the voltage value of the battery, as a backup for continuing driving of the electrically powered vehicle as long as possible while protecting the battery.

It is desirable to provide a vehicle control apparatus and a non-transitory recording medium that make it possible to indirectly estimate a voltage value of a battery even if it becomes difficult to directly measure the voltage value of the battery.

In the following, some example embodiments of the disclosure are described in detail with reference to the accompanying drawings. Note that the following description is directed to illustrative examples of the disclosure and not to be construed as limiting to the disclosure. Factors including, without limitation, numerical values, shapes, materials, components, positions of the components, and how the components are coupled to each other are illustrative only and not to be construed as limiting to the disclosure. Further, elements in the following example embodiments which are not recited in a most-generic independent claim of the disclosure are optional and may be provided on an as-needed basis. The drawings are schematic and are not intended to be drawn to scale. Throughout the present specification and the drawings, elements having substantially the same function and configuration are denoted with the same reference numerals to avoid any redundant description. In addition, elements that are not directly related to any embodiment of the disclosure are unillustrated in the drawings. Other configurations than those described in detail below may be complemented as appropriate by elemental techniques and configurations regarding known electrically powered vehicles, including JP-A No. 2014-205386.

### First Example Embodiment

### <Electrically Powered Vehicle 100>

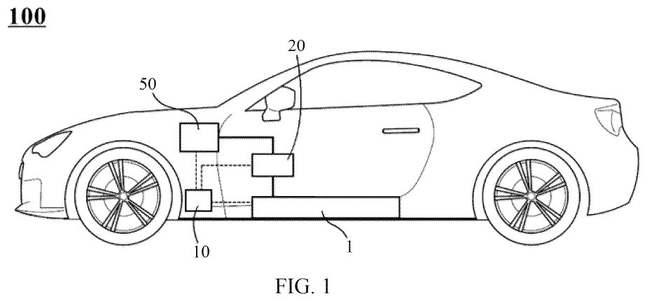

FIGS. 1 and 2 are schematic diagrams each illustrating a configuration example of an electrically powered vehicle 100 according to a first example embodiment. As the electrically powered vehicle 100 according to the example embodiment, various known electrically powered vehicles driven by an electric motor and mountable with a battery 1 to be described later may be applied. Examples of such known electrically powered vehicles may include an electric vehicle, a hybrid electric vehicle (HEV), and a plug-in hybrid electric vehicle (PHEV). In one embodiment, the electrically powered vehicle 100 may serve as a “vehicle”. As the battery 1 according to the example embodiment, various known secondary batteries such as a lithium-ion secondary battery or a nickel-metal hydride battery may be applied.

As illustrated in FIG. 1, the electrically powered vehicle 100 may be configured to supply electric power from the battery 1 to an electric motor 50 through a known converter 20, under the control of a vehicle control apparatus 10. The converter 20 according to the example embodiment may include a known AC/DC converter or a known DC/AC converter that appropriately performs conversion between a DC current and an AC current. The converter 20 may also include, for example, a known DC/DC converter that adjusts a voltage value of a DC current to a desired voltage value.

As illustrated in FIG. 2, the electrically powered vehicle 100 may be configured as, for example, a four-wheel drive vehicle that transmits a driving torque outputted from the electric motor 50 to a left front wheel 3LF, a right front wheel 3RF, a left rear wheel 3LR, and a right rear wheel 3RR (hereinafter, collectively referred to as “drive wheels 3” unless a distinction is to be made between them). The electric motor 50 may generate the driving torque of the vehicle.

The electric motor 50 according to the example embodiment is not particularly limited, and a known electric motor as exemplified in JP-A No. 2014-205386 may be applied. The electric motor 50 may output the driving torque to be transmitted to a front-wheel drive shaft 2F and a rear-wheel drive shaft 2R through a known transmission 51, a known front-wheel differential mechanism 5F, and a known rear-wheel differential mechanism 5R.

The example embodiment describes an example in which the single electric motor 50 distributes the driving torque to each wheel. Alternatively, one electric motor 50 may be disposed for each of the front wheel side and the rear wheel side, or one electric motor 50 may be disposed for each of the drive wheels 3. The electrically powered vehicle 100 according to the example embodiment may be configured as a four-wheel drive vehicle as described above, but may be a two-wheel drive vehicle in which the electric motor described above drives the front wheels or the rear wheels.

The electric motor 50 may be electrically coupled to the battery 1 through the above-described converter 20. The vehicle control apparatus 10 to be described later may perform control to supply electric power to be used to drive the electric motor 50 from the battery 1 through the converter 20, and to charge the battery 1 with electric power generated by the electric motor 50 at the time of regeneration through the converter 20.

The electrically powered vehicle 100 according to the example embodiment may include, for example, a known electric steering device 8 and known brake devices 4LF, 4RF, 4LR, and 4RR (hereinafter, collectively referred to as “brake devices 4” unless a distinction is to be made between them), as equipment to be used for driving control of the vehicle. In the example embodiment, the front-wheel drive shaft 2F may be provided with the above-described electric steering device 8. The electric steering device 8 may include an unillustrated known motor and unillustrated known gears that drive the electric steering. The electric steering device 8 may adjust a steering angle of the left front wheel 3LF and the right front wheel 3RF by being controlled by a control ECU 11.

The control ECU 11 may be mounted on the vehicle as one unit or multiple separate units. The control ECU 11 may be exemplified by one or more known electronic control units (ECUs) that control, for example, driving of the electric motor 50, the electric steering device 8, a steering wheel 9, and the brake devices 4 described above.

The vehicle control apparatus 10 may be configured as one of electronic control units (ECUs) described above. The vehicle control apparatus 10 may include one or more processors and one or more memories communicably coupled to the one or more processors. The processor may be, for example, a central processing unit (CPU). In addition, the vehicle control apparatus 10 may be configured to be coupled to a known external network NT such as the Internet through any of various known communication devices CD. The communication device CD may be, for example, communication through a smartphone interposed, or an in-vehicle communicator. The vehicle control apparatus 10 may be electrically coupled, directly or through an in-vehicle communication system such as a controller area network (CAN) or a local interconnect network (LIN), to the communication device CD described above, sensors SR, a known storage device MD, and a known notification device PD. Examples of the storage device MD may include a hard disk and a solid state drive (SSD). The notification device PD may include a speaker SP and a display DP.

The sensors SR may include, for example, a known voltage sensor SR₁, a known current sensor SR₂, a known acceleration sensor SR₃, and a known yaw rate sensor SR₄. The voltage sensor SR₁ is configured to detect a voltage value of the battery 1 described above. The current sensor SR₂ is configured to detect a current value of the battery 1 described above. The acceleration sensor SR₃ may be configured to detect an acceleration rate of the electrically powered vehicle 100 that is traveling. The yaw rate sensor SR₄ may be configured to detect a yaw rate of the electrically powered vehicle 100 that is traveling. The sensors SR according to the example embodiment may include, for example, a known in-vehicle sensor such as a vehicle speed sensor, an image sensor, or a gyro sensor, in addition to the above-described sensors.

### <Configuration of Vehicle Control Apparatus 10>

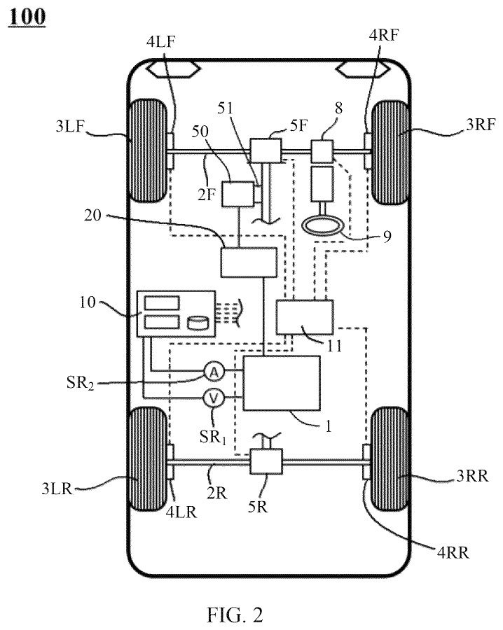

FIG. 3 illustrates a configuration example of the vehicle control apparatus 10 and peripheral devices thereof according to the example embodiment.

The electrically powered vehicle 100 may include the voltage sensor SR₁ and the current sensor SR₂, as described above. The voltage value etc. of the battery 1 may thus be detected through the voltage sensor SR₁ and the current sensor SR₂ as long as an abnormality such as a malfunction does not occur. However, for example, aging or a malfunction can cause some abnormality in the voltage sensor SR₁ and the current sensor SR₂, which can result in an abnormal situation in which the voltage value of the battery 1 is undetectable through the voltage sensor or the current sensor.

Such an abnormal situation may be coped with by estimating a state of charge (SOC) of the battery 1 in some known examples, but such an existing method merely estimates the SOC. It can thus be difficult by the existing method to accurately estimate the voltage of the battery that dynamically fluctuates with, for example, charging and discharging. Accordingly, it may be desired to use a method by which the voltage of the battery that changes every moment is more accurately estimable by considering various models as in the example embodiment. The various models may include a battery model and a vehicle motion model to be described later.

The vehicle control apparatus 10 is configured to estimate the voltage value of the battery 1 mounted on the vehicle, without using the voltage sensor SR₁ configured to measure the voltage value of the battery 1 or the current sensor SR₂ configured to measure the current value of the battery 1.

The vehicle control apparatus 10 includes a processor and a memory configured to store a program to be executed by the processor. The program includes a command. The command causes the processor to: calculate, as estimated values, a desired electric power amount and the current value that are estimated to be used to drive the vehicle; and estimate the voltage value of the battery based on the calculated estimated values of the desired electric power amount and the current value.

### <Units of Vehicle Control Apparatus 10>

As illustrated in FIG. 3, the vehicle control apparatus 10 may include a voltage measuring unit 10a, a voltage sensor malfunction determination unit 10b, a motor output estimation unit 10c, an electric power estimation unit 10d, a current estimation unit 10e, a voltage estimation unit 10f, and a notification control unit 10g.

### (Voltage Measuring Unit 10a)

The voltage measuring unit 10a may be configured to measure the voltage value of the battery 1 through the voltage sensor SR₁ described above. The voltage measuring unit 10a may measure the voltage value of the battery 1 at a predetermined timing, for example, in order to drive the electric motor 50 while the electrically powered vehicle 100 is traveling.

### (Voltage Sensor Malfunction Determination Unit 10b)

The voltage sensor malfunction determination unit 10b may be configured to determine whether there is a malfunction in the voltage sensor SR₁. For example, the voltage sensor malfunction determination unit 10b may determine whether there is a malfunction in the voltage sensor SR₁ based on whether the voltage value of the battery 1 measured by the voltage measuring unit 10a described above has entered an abnormal range. Values of the abnormal range may be determined in advance by an experiment or a simulation in accordance with a type or specifications of the battery 1 to be used.

Note that the voltage sensor malfunction determination unit 10b may determine whether there is a malfunction in the voltage sensor SR₁ by, for example, a known voltage sensor malfunction detection method exemplified in International Publication No. WO 2014/167644, in addition to the malfunction determination method described above.

### (Motor Output Estimation Unit 10c)

The motor output estimation unit 10c may acquire a requested torque in the vehicle, and estimate a motor output value based on the acquired requested torque and a rotational speed of the electric motor 50 at that time. The requested torque may be a torque requested of the electric motor 50 to be generated with operation on an accelerator by a driver who drives the vehicle. For example, the motor output estimation unit 10c may be configured to estimate the motor output value by multiplying the above-described requested torque by the rotational speed of the electric motor 50 at that time.

The requested torque for the electric motor 50 described above may be calculated, for example, by a known method based on a vehicle speed and an accelerator position. The motor output estimation unit 10c may calculate the requested torque for the electric motor 50 in accordance with, for example, known methods disclosed in JP-A Nos. 2016-096657 and 2020-100360, in addition to the above-described method.

### (Electric Power Estimation Unit 10d)

The electric power estimation unit 10d may estimate a desired electric power amount (output amount) to be supplied by the battery 1, based on the motor output value of the electric motor 50 estimated (calculated) by the motor output estimation unit 10c described above and an energy conversion efficiency factor on an electric power transfer path from the battery 1 to the electric motor 50. For example, the electric power estimation unit 10d may be configured to estimate the above-described desired electric power amount (output amount) to be supplied by the battery 1, by dividing the above-described motor output value by the energy conversion efficiency factor through the converter 20 and the electric motor 50. The converter 20 may be an inverter in this example.

Note that the above-described energy conversion efficiency factor may be obtained in advance, for example, by performing an experiment or a simulation. The energy conversion efficiency factor obtained in advance may be, for example, held as factor data in the above-described storage device MD, or downloaded from an external server etc. through the above-described communication device CD.

### (Current Estimation Unit 10e)

The current estimation unit 10e may estimate a current value flowing through the battery 1, based on the desired electric power amount (output amount) estimated by the electric power estimation unit 10d described above. For example, the current estimation unit 10e may be configured to estimate the current value flowing through the battery 1, by dividing the desired electric power amount (output amount) estimated by the electric power estimation unit 10d by the voltage value calculated at the time of the previous calculation. The vehicle control apparatus 10 may estimate the voltage value of the battery 1 at predetermined time intervals (e.g., 1 millisecond to 10 milliseconds) as will be described later. Accordingly, it is possible to use the voltage value of the battery 1 estimated At seconds (several milliseconds) earlier as the time of the previous calculation.

### (Voltage Estimation Unit 10f)

The voltage estimation unit 10f may estimate the voltage value (a terminal voltage) in the battery 1, by substituting the current value of the battery 1 estimated by the above-described current estimation unit 10e into an expression of a known battery model. As the expression of the battery model, the following voltage calculation expression based on a battery model using a known

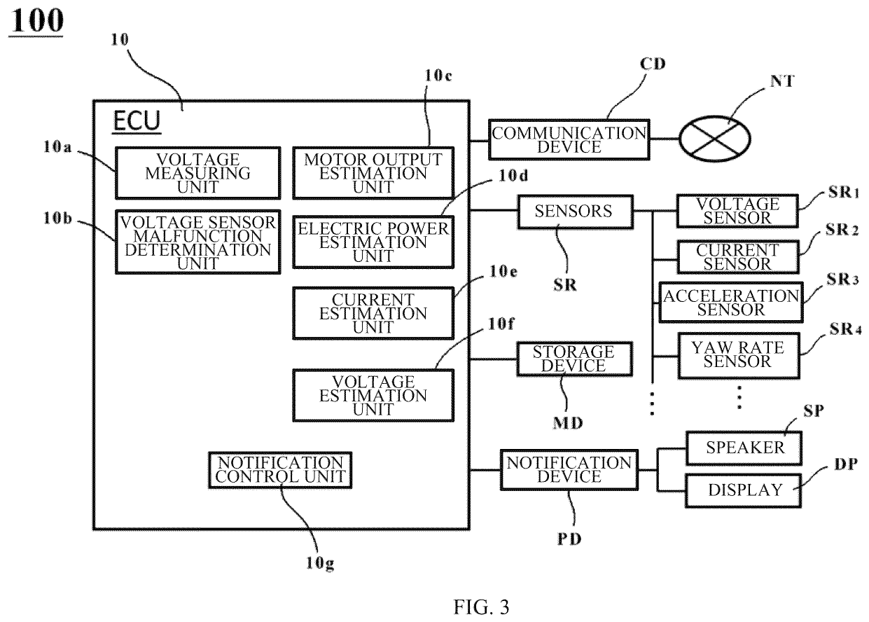

The battery model is exemplified resistance-capacitance (RC) equivalent circuit may be applied. in FIG. 4.

Battery voltage calculation expression:

V(tₖ)=V_{OCV}(SOC(tₖ))−R₀I(tₖ)−R₁I_{R1}(tₖ)

According to the above-described voltage calculation expression, a terminal voltage V(tₖ) of the battery 1 at a time tₖ may be calculated by subtracting, from an open-circuit voltage V_{OCV}, the product of a resistance R₀ and a current I(tₖ) and the product of a resistance R₁ and a current I_{R1}(tₖ). The resistance R₀ represents solution resistance of the battery. The resistance R₁ represents charge transfer resistance. Values of the open-circuit voltage V_{OCV}, the resistance R₀, and the resistance R₁ described above may be, for example, obtained in advance by an experiment or a simulation.

Note that the known RC equivalent circuit illustrated in FIG. 4 is an example of the battery model. The voltage estimation unit 10f may estimate the voltage value (terminal voltage) in the battery 1 by applying the above-described current value estimated by the current estimation unit 10e to other known battery models disclosed in, for example, JP-A Nos. 2014-74682 and 2017-138128.

### (Notification Control Unit 10g)

The notification control unit 10g may perform a process of providing notification of various pieces of information, such as whether there is a malfunction in the battery 1 or the estimated voltage value, through the above-described notification device PD including the speaker SP and the display DP. The notification control unit 10g may present the various pieces of information described above to an occupant through the notification device PD mounted on the vehicle, or perform control to provide notification by accessing an external terminal such as a smartphone carried by the occupant.

### <Voltage Estimation Method for Battery 1 Using Neither Voltage Sensor nor Current Sensor>

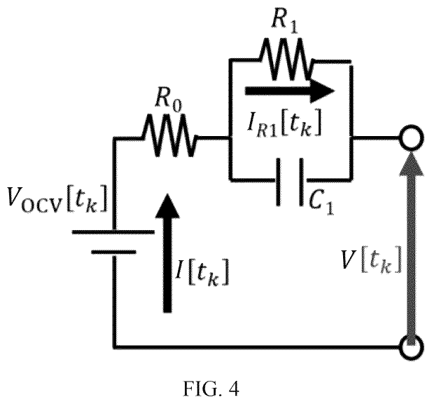

A voltage estimation method for the battery executable by the vehicle control apparatus 10 according to the example embodiment will now be described, referring also to FIG. 5. As described above, the voltage estimation method in this example may be implemented in the form of a program, and the program may be stored in a known non-transitory recording medium.

As illustrated in FIG. 5, in Step 1, the vehicle control apparatus 10 may determine whether an abnormality has occurred in the voltage sensor SR₁ mounted on the vehicle. For example, the voltage sensor malfunction determination unit 10b of the vehicle control apparatus 10 may determine whether there is a malfunction in the voltage sensor SR₁ based on whether the voltage value of the battery 1 measured by the voltage measuring unit 10a has entered an abnormal range.

When it is determined in Step 1 that there is no abnormality in the voltage sensor SR₁ (No in Step 1), in Step 2A, the vehicle control apparatus 10 may acquire the voltage value measured by the voltage sensor SR₁ operating normally. The vehicle control apparatus 10 may thus hold the value measured by the voltage sensor SR₁ as the voltage value of the battery 1. In addition, the vehicle control apparatus 10 may cause the process to return to Step 1 and repeat the processes when the system has not yet been turned OFF (No in Step 6).

When it is determined in Step 1 that an abnormality has occurred in the voltage sensor SR₁, indicating a malfunction, in Step 2B and subsequent steps, the vehicle control apparatus 10 may perform a process of estimating the voltage value of the battery 1 without using the voltage sensor SR₁ or the current sensor SR₂. The vehicle control apparatus 10 may first acquire data regarding the requested torque for the electric motor 50 in Step 2B. For example, the motor output estimation unit 10c of the vehicle control apparatus 10 may acquire the requested torque (the torque requested of the electric motor 50) in the vehicle by the known method described above.

Thereafter, in Step 3, the motor output estimation unit 10c of the vehicle control apparatus 10 may estimate the motor output value of the electric motor 50, based on the acquired requested torque and the rotational speed of the electric motor 50 at that time.

After the motor output value is estimated in Step 3, in Step 4, the vehicle control apparatus 10 may estimate the current value from the battery 1 corresponding to the motor output value described above. The electric power estimation unit 10d of the vehicle control apparatus 10 may estimate the desired electric power amount (output amount) to be supplied by the battery 1, based on the motor output value described above and the energy conversion efficiency factor from the battery 1 to the electric motor 50, as described above. The current estimation unit 10e of the vehicle control apparatus 10 may estimate the current value flowing through the battery 1 by the above-described method, based on the desired electric power amount (output amount) estimated above.

After the current value from the battery is estimated in Step 4, in Step 5, the vehicle control apparatus 10 may estimate the voltage value (terminal voltage) in the battery 1 based on the estimated current value flowing through the battery 1. For example, the voltage estimation unit 10f of the vehicle control apparatus 10 may estimate the voltage value (terminal voltage) in the battery 1 by substituting the current value of the battery 1 into the above-described expression of the battery model.

Through Steps 2B to 5 described above, it is possible for the vehicle control apparatus 10 to estimate the voltage value of the battery 1 with high accuracy without using the voltage sensor SR₁ or the current sensor SR₂ that has become unavailable due to some abnormality or malfunction.

After estimating the voltage value of the battery 1 in Step 5, the vehicle control apparatus 10 may cause the process to return to Step 1 and repeat the above-described processes, unless it is determined that the system has been turned OFF in Step 6. For example, the vehicle control apparatus 10 may repeat the processes of Steps 1 to 6 in a predetermined cycle (e.g., several milliseconds to several tens of milliseconds) to estimate the voltage value.

### <Non-Transitory Recording Medium>

As described above, the voltage estimation method for the battery described above may be implemented as a computer-readable voltage value estimation program. The vehicle control apparatus 10 may be configured to read the voltage value estimation program for the battery. The voltage value estimation program for the battery may be stored in a known non-transitory recording medium, as will be described later. Alternatively, the voltage value estimation program may be downloadable to the electrically powered vehicle 100, for example, from a known server such as a cloud.

As described above, the non-transitory recording medium according to the example embodiment is implemented as a non-transitory tangible computer readable recording medium containing a voltage value estimation program configured to estimate the voltage value of the battery mounted on the vehicle, without using the voltage sensor configured to measure the voltage value of the battery or the current sensor configured to measure the current value of the battery. The voltage value estimation program causes, when executed by a processor, the processor to implement a method. The method includes: calculating, as estimated values, a desired electric power amount and the current value that are estimated to be used to drive the vehicle; and estimating the voltage value of the battery based on the calculated estimated values of the desired electric power amount and the current value.

The non-transitory recording medium that contains a computer program may include: a magnetic medium such as a hard disk, a floppy disk, or a magnetic tape; an optical recording medium such as a compact disk read-only memory (CD-ROM), a digital versatile disk (DVD), or a Blu-ray (registered trademark); a magneto-optical medium such as a floptical disk; a storage element such as a random-access memory (RAM) or a read-only memory (ROM); a flash memory such as a universal serial bus (USB) memory; a solid state drive (SSD); or any other medium configured to store a program.

In the vehicle control apparatus 10 and the electrically powered vehicle 100 including the vehicle control apparatus 10 according to the first example embodiment described above, it is possible to indirectly estimate the voltage value of the battery based on the requested torque for the electric motor, even if an abnormality occurs in the voltage sensor or the current sensor and it becomes difficult to directly measure the voltage value of the battery.

### Second Example Embodiment

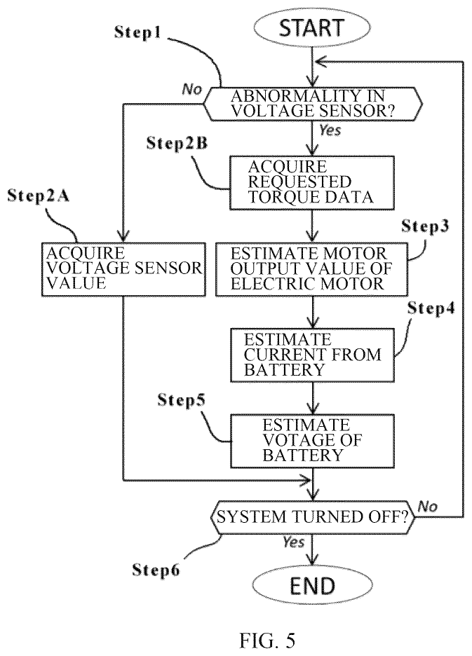

Now, an electrically powered vehicle 110 and a voltage estimation method for the battery 1 according to a second example embodiment will be described with reference to FIGS. 6 to 8.

The vehicle control apparatus 10 in the electrically powered vehicle 110 according to the example embodiment may further include an acceleration rate acquisition unit 10h, as compared with the above-described first example embodiment. In the first example embodiment, the vehicle control apparatus 10 may estimate the motor output value of the electric motor 50 using the requested torque for the motor. In contrast, the vehicle control apparatus 10 according to the example embodiment may estimate the motor output value of the electric motor 50 mainly using data regarding the acceleration rate, i.e., acceleration rate data, of the vehicle traveling straight ahead.

In determining whether the vehicle is traveling straight ahead, the vehicle control apparatus 10 may regard the vehicle as traveling straight ahead when, for example, the steering angle of the steering wheel 9 is within a predetermined angle. The method of determining whether the vehicle is traveling straight ahead is not limited to the above, and other various known methods such as detection using a gyro sensor may be applied. In addition, the vehicle control apparatus 10 may detect a front road situation of the vehicle based on, for example, map data of a navigation device mounted on the vehicle, and determine whether the vehicle is traveling straight ahead in accordance with the front road situation.

### (Acceleration Rate Acquisition Unit 10h)

The acceleration rate acquisition unit 10h may be configured to acquire the acceleration rate data of the vehicle that is traveling through the acceleration sensor SR₃ mounted on the electrically powered vehicle 110. The acceleration rate acquisition unit 10h according to the example embodiment may obtain the acceleration rate of the vehicle from the acceleration sensor SR₃, but is not limited thereto. The acceleration rate acquisition unit 10h may calculate the acceleration rate by performing a differentiation process using values of a known vehicle speed sensor or a known position data sensor mounted on the vehicle.

### <Voltage Estimation Method for Battery 1 Using Neither Voltage Sensor nor Current Sensor>

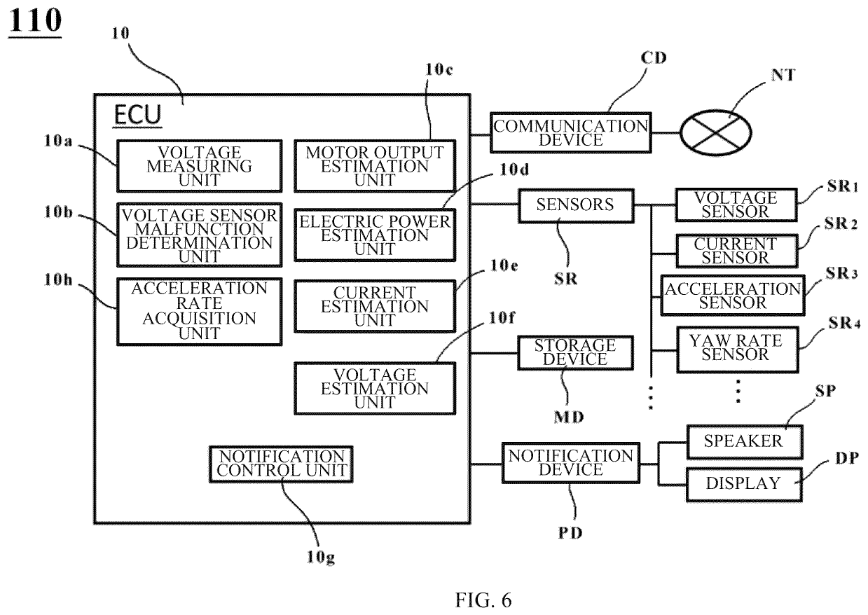

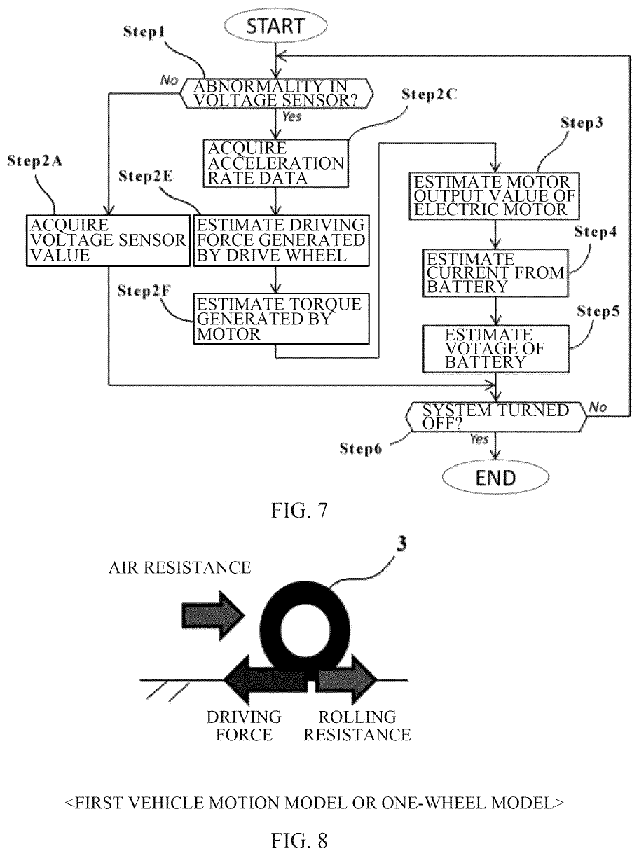

A voltage estimation method for the battery executable by the vehicle control apparatus 10 according to the second example embodiment will now be described, referring also to FIGS. 7 and 8. In the voltage estimation method described below, description of the same configurations as in the first example embodiment described above will be omitted as appropriate.

First, in Step 1, the vehicle control apparatus 10 may determine whether there is a malfunction in the voltage sensor SR₁ in a manner similar to that in the first example embodiment. When there is no abnormality in the voltage sensor SR₁ in Step 1, the vehicle control apparatus 10 may hold the value measured by the voltage sensor SR₁ as the voltage value of the battery 1 in Step 2A. When an abnormality has occurred in the voltage sensor SR₁ in Step 1, the vehicle control apparatus 10 may estimate the voltage value of the battery 1 mainly using the data obtained from the acceleration sensor SR₃ in Step 2C and subsequent steps.

In Step 2C, the acceleration rate acquisition unit 10h of the vehicle control apparatus 10 may acquire the acceleration rate data of the electrically powered vehicle 110 that is traveling through the acceleration sensor SR₃ described above.

After acquiring the acceleration rate data of the electrically powered vehicle 110, in Step 2E, the motor output estimation unit 10c of the vehicle control apparatus 10 may estimate a driving force generated by the drive wheel 3 of the electrically powered vehicle 110 by the following method.

In this example, assuming that the electrically powered vehicle 110 is accelerated at an acceleration rate α at a time t, the current value flowing from the battery 1 at this time may be estimated using a known vehicle motion model. As illustrated in FIG. 8, a first vehicle motion model (one-wheel model) in which the electrically powered vehicle 110 is simplified as including one wheel without considering a center of gravity movement, a yaw motion, etc. may be applied in this example. Alternatively, a known multi-wheel model such as a two-wheel model may be applied.

In this case, an estimated value of a driving force F generated by the drive wheel 3 for the electrically powered vehicle 110 to obtain the acceleration rate α, under a resistance force received by the vehicle, may be obtained using the following calculation expression. The resistance force may be simplified and limited to air resistance, rolling resistance, and gradient resistance in this example.

Driving force F generated between drive wheel 3 and road surface=vehicle weight×acceleration rate α

The “vehicle weight” in the above calculation expression may be obtained in advance by an experiment or a simulation. Note that the “vehicle weight” in the above calculation expression may be detected at an appropriate timing using a known tire force sensor or another known hub sensor disclosed in, for example, JP-A No. 2006-349440, instead of the above-described experiment or simulation.

Thus, in Step 2E, the motor output estimation unit 10c of the vehicle control apparatus 10 may estimate the driving force generated by the drive wheel 3 of the electrically powered vehicle 110, from the acceleration rate obtained in Step 2C and data regarding the vehicle weight held in advance.

In Step 2F, the motor output estimation unit 10c of the vehicle control apparatus 10 may estimate the torque generated by the electric motor 50 by the following method. Because the resistance force (e.g., the air resistance, the rolling resistance, and the gradient resistance described above) received by the vehicle is calculable in advance by an experiment or a simulation as described above, a torque T desired in the electric motor 50 may be calculated using the following expression.

Torque T outputted by motor=(driving force F generated between drive wheel 3 and road surface+resistance force received by vehicle)×tire radius/shifting ratio

Note that the above-described air resistance received by the vehicle may be calculated by a known method disclosed in, for example, JP-A Nos. 2014-080128 and 2023-036347. The rolling resistance received by the vehicle may be calculated by a known method disclosed in, for example, JP-A Nos. 2009-045957 and 2014-080128. The gradient resistance received by the vehicle may be, for example, calculated using “vehicle body weight×sin θ” based on an inclination (gradient angle θ) in a vehicle longitudinal direction from a horizontal plane by a gyro sensor mounted on the vehicle. Alternatively, the gradient resistance received by the vehicle may be calculated by a known method disclosed in, for example, JP-A No. 2020-010454.

Thus, in Step 2F, the motor output estimation unit 10c of the vehicle control apparatus 10 may estimate the torque T outputted by the electric motor 50 using the above-described calculation expression, based on the driving force F estimated in Step 2E and data regarding the resistance force received by the vehicle, the tire radius, and the shifting ratio each held in advance.

After estimating the torque T outputted by the electric motor 50 in Step 2F, in Step 3, the motor output estimation unit 10c of the vehicle control apparatus 10 may estimate the motor output value by multiplying the torque T outputted by the electric motor 50 by the rotational speed of the electric motor 50 at that time.

After the motor output value is estimated in Step 3, in Step 4, the vehicle control apparatus 10 may estimate the current value from the battery 1 corresponding to the motor output value described above. The electric power estimation unit 10d of the vehicle control apparatus 10 may estimate the desired electric power amount (output amount) to be supplied by the battery 1, based on the motor output value described above and the energy conversion efficiency factor from the battery 1 to the electric motor 50. The current estimation unit 10e of the vehicle control apparatus 10 may estimate the current flowing through the battery 1 by the method described in the first example embodiment, based on the desired electric power amount (output amount) estimated above.

Based on the first example embodiment and the second example embodiment described above, the vehicle control apparatus 10 according to an embodiment of the disclosure may calculate the desired electric power amount based on one or both of the acceleration rate acquired from the vehicle and the requested torque in the vehicle.

The processes of Step 5 and subsequent steps may be similar to those in the above-described first example embodiment, and description thereof will be omitted.

The vehicle control apparatus 10 and the electrically powered vehicle 110 according to the second example embodiment described above make it possible to, for example, in the vehicle that is traveling straight head, indirectly estimate the voltage value of the battery through the acceleration sensor, even if an abnormality occurs in the voltage sensor or the current sensor and it becomes difficult to directly measure the voltage value of the battery.

### Modifications

In the second example embodiment described above, the motor output value of the electric motor 50 may be estimated mainly using the acceleration rate data of the vehicle traveling straight ahead. In some embodiments, the motor output value of the electric motor 50 at the time of turning of the vehicle may also be estimated as follows. When the vehicle turns at, for example, a curve, a lateral force is generated on a tire for the turning.

In the turning described above, the lateral force may thus be applied as the “resistance force received by the vehicle”. Accordingly, the resistance force caused by the lateral force may be incorporated into the “resistance force received by the vehicle” in the above-described expression of the torque T. As a method of calculating the resistance force caused by the lateral force, the resistance force caused by the lateral force may be calculated in advance by an experiment or a simulation, or a known estimation method disclosed in, for example, JP-A No. 2007-331659 may be applied.

Further, the vehicle control apparatus 10 may detect the front road situation of the vehicle based on, for example, the map data of the navigation device mounted on the vehicle, and estimate the motor output value of the electric motor 50 described above after determining whether the vehicle is turning in accordance with the front road situation.

Although some example embodiments of the disclosure have been described in the foregoing by way of example with reference to the accompanying drawings, the disclosure is by no means limited to the embodiments described above. It should be appreciated that modifications and alterations may be made by persons skilled in the art without departing from the scope as defined by the appended claims. The disclosure is intended to include such modifications and alterations in so far as they fall within the scope of the appended claims or the equivalents thereof.

The vehicle control apparatus 10 illustrated in FIG. 3 is implementable by circuitry including at least one semiconductor integrated circuit such as at least one processor (e.g., a central processing unit (CPU)), at least one application specific integrated circuit (ASIC), and/or at least one field programmable gate array (FPGA). At least one processor is configurable, by reading instructions from at least one machine readable non-transitory tangible medium, to perform all or a part of functions of the vehicle control apparatus 10. Such a medium may take many forms, including, but not limited to, any type of magnetic medium such as a hard disk, any type of optical medium such as a CD and a DVD, any type of semiconductor memory (i.e., semiconductor circuit) such as a volatile memory and a non-volatile memory. The volatile memory may include a DRAM and a SRAM, and the nonvolatile memory may include a ROM and a NVRAM. The ASIC is an integrated circuit (IC) customized to perform, and the FPGA is an integrated circuit designed to be configured after manufacturing in order to perform, all or a part of the functions of the vehicle control apparatus 10 illustrated in FIG. 3.

1. A vehicle control apparatus configured to estimate a voltage value of a battery mounted on a vehicle, without using a voltage sensor configured to measure the voltage value of the battery or a current sensor configured to measure a current value of the battery, the vehicle control apparatus comprising:
a processor, and
a memory configured to store a program to be executed by the processor, wherein the program comprises a command, and
the command causes the processor to execute a processing including
calculating, as estimated values, a desired electric power amount and the current value that are estimated to be used to drive the vehicle, and
estimating the voltage value of the battery, based on the calculated estimated values of the desired electric power amount and the current value.

2. The vehicle control apparatus according to claim 1, wherein the desired electric power amount is calculated based on one or both of an acceleration rate acquired from the vehicle and a requested torque in the vehicle.

3. The vehicle control apparatus according to claim 2, wherein
the command further causes the processor to determine a front road situation of the vehicle that is traveling, and
the estimating the voltage value of the battery comprises estimating the voltage value of the battery based on data regarding the acceleration rate of the vehicle, in accordance with the front road situation.

4. A non-transitory tangible computer readable recording medium containing a voltage value estimation program configured to estimate a voltage value of a battery mounted on a vehicle, without using a voltage sensor configured to measure the voltage value of the battery or a current sensor configured to measure a current value of the battery, the voltage value estimation program causing, when executed by a processor, the processor to implement a method, the method comprising:
calculating, as estimated values, a desired electric power amount and the current value that are estimated to be used to drive the vehicle; and
estimating the voltage value of the battery, based on the calculated estimated values of the desired electric power amount and the current value.
